(19) United States
(12) Patent Application Publication
(10) Pub. No.: US 2006/0239472 A1
(43) Pub. Date: Oct. 26, 2006

(54) Sound quality adjusting apparatus and sound quality adjusting method

(75) Inventor: Mikio Oda, Yawata-shi, Kyoto (JP)

Correspondence Address: GREENBLUM & BERNSTEIN, P.L.C., 1950 ROLAND CLARKE PLACE, RESTON, VA, 20191, US

(73) Assignee: Matsushita Electric Industrial Co., Ltd., Osaka (JP)

(21) Appl. No.: 10/558,704

(22) PCT Filed: Jun. 4, 2004
(86) PCT No.: PCT/JP04/08161

§ 371 Date: Nov. 29, 2005

(30) Foreign Application Priority Data
Jun. 5, 2003 (JP) 2003-160264

(51) Int. Cl. H03G 5/00

(52) U.S. Cl. 381/98

(57) ABSTRACT

An LPF extracts a medium and low frequency component of an inputted sound signal. An HPF extracts a high and low frequency component in the inputted sound signal. One of the two level detectors determines whether the medium and low frequency component exists by detecting the level of an output signal of the LPF. The other level detector determines whether the high frequency component exists by detecting the level of an output signal of the HPF. An inverter inverts the level of an output signal of the one level detector. An AND gate operates an AND of an output signal of the inverter and an output signal of the other level detector. An integrator integrates an output signal of the AND gate. A VCA determines that the sound signal is a sibilant when the medium and low frequency component does not exist and when the high frequency component exists, and attenuates the level of the output signal of the HPF, while the VCA determines that the sound signal is a normal speech sound when the medium and low frequency component exist and outputs the output signal of the HPF without modification. An adder synthesizes the output signal of the LPF and the output signal of the VCA by addition.

### TECHNICAL FIELD

The present invention relates to a sound quality adjusting device and a sound quality adjusting method that adjusts the sound quality of a reproduced sound.

### BACKGROUND ART

With the start of BS (satellite) broadcasting, sound signals in a current television system have come to be transmitted in a digital signal format, having a wide frequency band from a low frequency range to a high frequency range, flat frequency characteristics, and a high quality with less noise. On the other hand, speakers mounted on a television set that reproduces such sound signals are limited in size and shape due to restrictions on space caused by being incorporated into the television set and on cost. Therefore, it is difficult for the speakers of a television set to have flat frequency characteristics in a low frequency range to a high frequency range.

Consequently, there are proposed various methods for improving the sound quality at the time of reproduction (JP 2002-513479 A).

Furthermore, there is a problem that because of the disturbance of frequency characteristics of a high frequency range, the pronunciation of “sa”, “shi”, “su”, “se” and “so” in words that an announcer utters is markedly emphasized, which sounds harshly to the ear. These sounds are generally referred to as sibilants, and it is known that when pronouncing “sa”, “shi” “su”, “se” and “so”, air hits anterior teeth to produce the sibilants. These sibilants are different among individuals, depending on how to pronounce, and thus, there are various cases such as a voice sound in which the sibilants are not so harsh and a voice sound which the sibilants make it hard to hear.

In a broadcasting station, in order to suppress the sibilants in the voice sound hard to hear, a sound quality adjusting device called De-Esser is used, which is a type of effecter, as professional sound equipment.

FIG. 9 is a block diagram showing one example of the De-Esser. A description of the De-Esser is given below, in reference to FIG. 9.

The De-Esser in FIG. 9 includes a low pass filter (hereinafter abbreviated to LPF) 21, a band pass filter (hereinafter abbreviated to BPF) 22, a high pass filter (hereinafter abbreviated to HPF) 23, a compressor 24, and an adder 25.

The LPF 21 allows a medium and low frequency component of an inputted sound signal to pass. The BPF 22 allows only a medium and high frequency component of the inputted sound signal to pass. HPF 22 allows only a high frequency component of the inputted sound signal to pass. The compressor 24 compresses the level of a sound signal outputted from the BPF 24. The adder 25 synthesizes a sound signal outputted from the LPF 21, a sound signal outputted from the compressor 24 and a sound signal outputted from the HPF 23 by addition.

The operation of the De-Esser configured in this manner is described using FIGS. 10 and 11. FIG. 10 is a diagram showing frequency characteristics of the LPF 21, the BPF 22 and the HPF 23 in the De-Esser of FIG. 9. FIG. 11 is a diagram showing a characteristic example of the compressor 24 in the De-Esser of FIG. 9.

In the broadcasting station, a voice sound generated by an announcer or the like is converted to a sound signal which is an electric signal by a microphone, and is amplified to a predetermined level by a microphone amplifying device, and the amplified sound signal is inputted into sound processing equipment for broadcasting.

When the sibilants in the utterance of the announcer are so markedly strong that the voice sound is hard to hear, the insertion of the De-Esser of FIG. 9 into the latter stage of the microphone amplifying device reduces the sibilants as follows.

Normally, the frequency band of a sibilant is said to range from 5 kHz to 10 kHz, and the component of this frequency band is extracted by the BPF 22 in the De-Esser of FIG. 9. Components of the frequency band other than this pass through the LPF 21 and the HPF 23. The component of the frequency band extracted by the BPF 22 is compressed by the compressor 24. As shown in FIG. 11, when the input level exceeds a threshold level Ls, the compressor 24 compresses the output level.

The sound signal outputted from the LPF 21, the sound signal outputted from the compressor 24 and the sound signal from the HPF 23 are added by the adder 25.

In this manner, by the De-Esser, the signal level of the frequency band of the sibilants is attenuated, so that the sibilants are made unremarkable.

Furthermore, some De-Essers can vary the pass band in the BPF, the compression level and the threshold level. In this case, the adjustment in accordance with the sound quality of an announcer is enabled.

It is considered that this technique of the De-Esser is applied to a television set for domestic use, thereby reducing harsh sibilants in the television set.

Although an effect of reduction of the sibilants can be obtained when a voice sound is recorded using the De-Esser in the broadcasting station, however, when the De-Esser is used to reduce the sibilants harsh to the ear that remain a sound obtained by receiving television broadcasting, not only the sibilants in the pass band of the BPF are reduced, but also BGM (background music) or sound effects mixed with the audio sound are reduced, thereby resulting in the sound quality in which the high frequency component is removed.

### DISCLOSURE OF THE PRESENT INVENTION

An object of the present invention is to provide a sound quality adjusting device capable of reducing sibilants without causing deterioration in sound quality of a high frequency component of a reproduced sound signal, and a sound quality adjusting method.

A sound quality adjusting device according to one aspect of the present invention includes a determination unit that determines whether a component of a predetermined first frequency band exists in an inputted sound signal; and a controller that attenuates a component of a second frequency band higher than the first frequency band in the inputted sound signal and outputs the sound signal in which the component of the second frequency band is attenuated when the determination unit has determined that the component of the first frequency band does not exist, and that outputs the inputted sound signal without attenuating the component of the second frequency band in the inputted sound signal when the determination unit has determined that the component of the first frequency band exists.

In the above sound quality adjusting device, whether the component of the predetermined first frequency band exists in the inputted sound signal is determined by the determination unit. Namely, based on whether there is the component of the first frequency band which is a medium and low frequency component, it is determined if the sound signal is a sibilant.

When it is determined that the component of the first frequency band does not exist, the component of the second frequency band higher than the first frequency band in the inputted sound signal is attenuated by the controller and the sound signal in which the second frequency band is attenuated is outputted. Namely, when the component of the first frequency band which is the medium and low frequency component does not exist, the sound signal is considered to be the sibilant and the component of the second frequency band is attenuated. Thus, the sibilants that sound harshly to the ear are reduced, and a sound easy to hear is reproduced.

On the other hand, when it is determined that the component of the first frequency band exists, the inputted sound signal is outputted without attenuating the component of the second frequency band in the inputted sound signal by the controller. Namely, when the component of the first frequency band which is the medium and low frequency component exists, the sound signal is considered to be a normal speech sound, and the component of the second frequency band is not attenuated. This prevents deterioration in sound quality of the high frequency component. In this case, by outputting the medium and low frequency component and the high frequency component, a balanced sound which is easy to hear is reproduced.

The determination unit may determine that the component of the first frequency band exists when a level of the component of the first frequency band in the inputted sound signal is equal to or higher than a predetermined value, and that the component of the first frequency band does not exist when the level of the component of the first frequency band in the inputted sound signal is lower than the predetermined value.

In this case, it is determined that the component of the first frequency band exists when the level of the component of the first frequency band in the inputted sound signal is equal to or higher than the predetermined value, while it is determined that the component of the first frequency band does not exist when the level of the component of the first frequency band in the inputted sound signal is lower than the predetermined value. Thus, it can be surely determined whether the sound signal is a sibilant or a normal speech sound.

The determination unit may include a first extractor that extracts the component of the first frequency band in the inputted sound signal; and a detector that detects whether a level of an output signal of the first extractor is equal to or higher than a predetermined value in order to determine whether the component of the first frequency band exists, and the controller may include a second extractor that extracts the component of the second frequency band in the inputted sound signal; an attenuator that attenuates a level of an output signal of the second extractor when the detector has detected that the level of the output signal of the first extractor is not equal to or higher than the predetermined value, and that outputs the output signal of the second extractor without attenuating when the detector has detected that the level of the output signal of the first extractor is equal to or higher than the predetermined value; and a synthesizer that synthesizes the output signal of the first extractor and an output signal of the attenuator.

In this case, the component of the first frequency band in the inputted sound signal is extracted by the first extractor. Further, in order to determine whether the component of the first frequency band exists, the detector detects whether the level of the output signal of the first extractor is equal to or higher than the predetermined value. Moreover, the component of the second frequency band of the inputted sound signal is extracted by the second extractor.

When the detector has detected that the level of the output signal of the first extractor is not equal to nor higher than the predetermined, the level of the output signal of the second extractor is attenuated by the attenuator. When the detector has detected that the level of the output signal of the first extractor is equal to or higher than the predetermined value, the output signal of the second extractor is outputted without being attenuated by the attenuator. The output signal of the first extractor and the output signal of the attenuator are synthesized by the synthesizer. Thus, the sibilants can be surely reduced without causing deterioration in sound quality of the high frequency component of the reproduced sound signal.

The determination unit may further include an integrator that integrates an output signal of the detector. In this case, the effect of chattering caused in the output signal of the detector is removed.

The first extractor may include a low pass filter, and the second extractor may include a high pass filter.

In this case, the medium and low frequency component in the inputted sound signal passes through the low pass filter, by which the component of the first frequency band is extracted. Further, the high frequency band in the inputted sound signal passes through the high pass filter, by which the component of the second frequency band is extracted.

The determination unit may determine whether the component of the first frequency band and the component of the second frequency band exist in the inputted sound signal, and the controller may attenuate the component of the second frequency band in the inputted sound signal when the determination unit has determined that the component of the first frequency band does not exist and the component of the second frequency band exists.

In this case, whether the component of the first frequency band and the component of the second frequency band exist in the inputted sound signal are determined by the determination unit. The component of the second frequency band in the inputted sound signal is attenuated by the controller when the determination unit has determined that the component of the first frequency band does not exist and the component of the second frequency band exists. Thus, the sibilants can be attenuated precisely and surely.

The determination unit may determine that the component of the first frequency band exists when a level of the component of the first frequency band in the inputted sound signal is equal to or higher than the predetermined value, and that the component of the first frequency band does not exist when the level of the component of the first frequency band in the inputted sound signal is lower than the predetermined value, and the determination unit may further determine that the component of the second frequency band exists when a level of the component of the second frequency band in the inputted sound signal is equal to or higher than a predetermined value, and determines that the component of the second frequency band does not exist when the level of the component of the second frequency band in the inputted sound signal is lower than the predetermined value.

In this case, when the level of the component of the first frequency band in the inputted sound signal is equal to or higher than the predetermined value, it is determined that the component of the first frequency band exists, while when the level of the component of the first frequency band in the inputted sound signal is lower than the predetermined value, it is determined that the component of the first frequency band does not exist. Furthermore, when the level of the component of the second frequency band in the inputted sound signal is equal to or higher than the predetermined value, it is determined that the component of the second frequency band exists, while when the level of the component of the second frequency band in the inputted sound signal is lower than the predetermined value, it is determined that the component of the second frequency band does not exist. Thereby, it can be surely determined whether the sound signal is a sibilant or a normal speech sound.

The determination unit may include a first extractor that extracts the component of the first frequency band in the inputted sound signal; a second extractor that extracts the component of the second frequency band in the inputted sound signal; a first detector detects whether a level of an output signal of the first extractor is equal to or higher than a predetermined value in order to determine whether the component of the first frequency band exists; and a second detector that detects whether a level of an output signal of the second extractor is equal to or higher than a predetermined value in order to determine whether the component of the second frequency band exists, and the controller may include an attenuator that attenuates the level of the output signal of the second extractor when the first detector has detected that the level of the output signal of the first extractor is not equal to nor higher than the predetermined value and when the second detector has detected that the level of the output signal of the second extractor is equal to or higher than the predetermined value, and that outputs the output signal of the second extractor without attenuating when either the first detector has detected that the level of the output signal of the first extractor is equal to or higher than the predetermined value or the second detector has detected that the level of the output signal of the second extractor is not equal to nor higher than the predetermined value; and a synthesizer that synthesizes the output signal of the first extractor and an output signal of the attenuator.

In this case, the component of the first frequency band in the inputted sound signal is extracted by the first extractor. Further, the component of the second frequency band in the inputted sound signal is extracted by the second extractor. Moreover, in order to determine the presence of the component of the first frequency band, the first detector detects whether or not the level of the output signal of the first extractor is equal to or higher than the predetermined value. In addition, in order to determine the presence of the component of the second frequency band, the second detector detects whether or not the level of the output signal of the second extractor is equal to or higher than the predetermined value.

When the first detector has detected that the level of the output signal of the first extractor is not equal to nor higher than the predetermined value, and when the second detector has detected that the level of the output signal of the second extractor is equal to or higher than the predetermined value, the level of the output signal of the second extractor is attenuated by the attenuator. When the first detector has detected that the level of the output signal of the first extractor is equal to or higher than the predetermined value or when the second detector has detected that the level of the output signal of the second extractor is not equal to nor higher than the predetermined value, the output signal of the second extractor is outputted without being attenuated by the attenuator. The output signal of the first extractor and the output signal of the attenuator are synthesized by the synthesizer. Thus, the sibilants can be surely reduced without causing deterioration in sound quality of the high frequency component of the reproduced sound signal.

The determination unit may further include an inverter that inverts an output signal of the first detector; and a logical operation unit that calculates an AND of an output signal of the inverter and an output signal of the second detector, and the attenuator may either attenuate or not attenuate, based on an output signal of the logical operation unit, the level of the output signal of the second extractor.

In this case, the output signal of the first detector is inverted by the inverter and the AND of the output signal of the inverter and the output signal of the second detector is calculated by the logical operation unit. Further, the level of the output signal of the second extractor is attenuated or not attenuated by the attenuator, based on the output signal of the logical operation unit. Thus, when it is determined that the sound signal is the sibilant, the high frequency component can be surely attenuated, and when it is determined that the sound signal is a normal speech sound, the attenuation of the high frequency component can be surely stopped.

The determination unit may further include an integrator that integrates the output signal of the logical operation unit. In this case, the effect of chattering caused in the output signal of the logical operation unit is removed.

The first extractor may include a low pass filter, and the second extractor may include a high pass filter.

In this case, the medium and low frequency component in the inputted sound signal passes through the low pass filter, by which the component of the first frequency component can be extracted. Further, the high frequency component in the inputted sound signal passes through the high pass filter, by which the component of the second frequency component can be extracted.

The first frequency band may be within a frequency band not higher than 5 kHz, and the first frequency band may be within a frequency band not lower than 5 kHz.

The sibilants have a spectrum component in the frequency band of 5 kHz to 10 kHz. Accordingly, the sibilants can be surely attenuated while preventing deterioration in sound quality of the high frequency component. As a result, a balanced sound which is easy to hear can be reproduced.

A sound quality adjusting method according to another aspect of the present invention includes the steps of determining whether a component of a predetermined first frequency band exists in an inputted sound signal; and attenuating a component of a second frequency band higher than the first frequency band in the inputted sound signal and outputting the sound signal in which the second frequency band is attenuated when determined that the component of the first frequency band does not exist, and outputting the inputted sound signal without attenuating the component of the second frequency band in the inputted sound signal when determined that the component of the first frequency band exists.

In the above sound quality adjusting method, whether the component of the predetermined first frequency band exists in the inputted sound signal is determined. Namely, based on whether the component of the first frequency band which is the medium and low frequency component exists, it is determined if the sound signal is the sibilant.

When it is determined that the component of the first frequency band does not exist, the component of the second frequency band higher than_the first frequency band in the inputted sound signal is attenuated, and the sound signal in which the second frequency band is attenuated is outputted. Namely, when the component of the first frequency band which is the medium and low frequency component does not exist, the sound signal is considered to be the sibilant and the component of the second frequency band is attenuated. Thus, the sibilants that sound harshly to the ear are reduced, so that a sound easy to hear is reproduced.

On the other hand, when it is determined that the component of the first frequency band exists, the inputted sound signal is outputted without being attenuated the component of the second frequency band in the inputted sound signal. Namely, when the component of the first frequency band which is the medium and low frequency component exists, the sound signal is considered to be a normal speech sound, and the component of the second frequency band is not attenuated. Thus, deterioration in sound quality of the high frequency component is prevented. In this case, by outputting the medium and low frequency component and the high frequency component, a balanced sound which is easy to hear is reproduced.

The step of determining may include the step of determining whether the component of the first frequency band and the component of the second frequency band exists in the inputted sound signal, and the step of outputting includes the step of attenuating the component of the second frequency band in the inputted sound signal when determined that the component of the first frequency band does not exist and the component of the second frequency band exists.

In this case, whether the component of the first frequency band and the component of the second frequency band exists in the inputted sound signal are determined. When it is determined that the component of the first frequency band does not exist and that the component of the second frequency band exists, the component of the second frequency band in the inputted sound signal is attenuated. Thus, the sibilants can be attenuated precisely and surely.

The first frequency band may be within a frequency band not higher than 5 kHz, and the first frequency band may be within a frequency band not lower than 5 kHz.

The sibilants have a spectrum component in the frequency band of 5 kHz to 10 kHz. Accordingly, the sibilants can be surely attenuated while preventing deterioration in sound quality of the high frequency component. As a result, a balanced sound which is easy to hear can be reproduced.

### BRIEF DESCRIPTION OF THE DRAWINGS

FIG. 1 is a block diagram showing a configuration of a sound quality adjusting device according to a first embodiment of the present invention.

FIG. 2 is signal waveform diagrams of respective sections in the sound quality adjusting device of FIG. 1.

FIG. 3 is a diagram showing one example of a waveform of a sibilant and a diagram showing one example of a frequency spectrum of the sibilant.

FIG. 4 is a diagram showing one example of a waveform of a normal speech sound and a diagram showing one example of a frequency spectrum of the normal speech sound.

FIG. 5 is a block diagram showing a configuration of a sound quality adjusting device according to a second embodiment of the present invention.

FIG. 6 is signal waveform diagrams of respective sections in the sound quality adjusting device of FIG. 5.

FIG. 7 is a diagram showing a measurement result of a spectrum of an uttered word.

FIG. 8 is a diagram showing a measurement result of a spectrum of a sound, sound quality of which has been adjusted.

FIG. 9 is a block diagram showing one example of a De-Esser.

FIG. 10 is a diagram showing a frequency characteristic example of an LPF, a BPF and an HPF in the De-Esser of FIG. 9.

FIG. 11 is a diagram showing a characteristic example of a compressor 24 in the De-Esser of FIG. 9.

### BEST MODE FOR CARRYING OUT THE INVENTION

Hereinafter, the embodiments of the present invention are described, referring to the drawings.

### First Embodiment

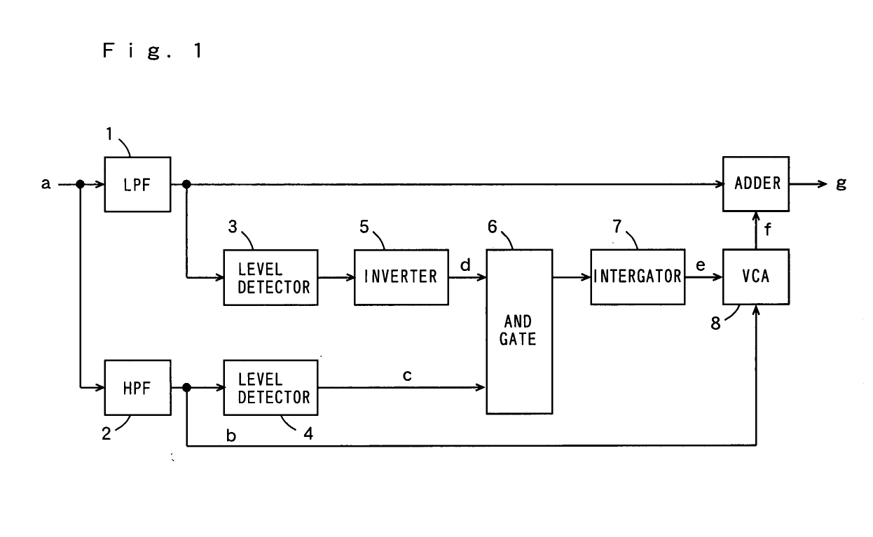

FIG. 1 is a block diagram showing a configuration of a sound quality adjusting device according to a first embodiment of the present invention.

The sound quality adjusting device of FIG. 1 includes a low pass filter (hereinafter, abbreviated to LPF), a high pass filter (hereinafter, abbreviated to HPF) 2, level detectors 3 and 4, an inverter 5, an AND gate 6, an integrator 7, a volume control amplifier (hereinafter, abbreviated to VCA) 8, and an adder 9.

The LPF 1 extracts a medium and low frequency component by passing the medium and low frequency component of not higher than 5 kHz of an inputted sound signal. The HPF 2 extracts a high and low frequency component by passing a high frequency component of not higher than 5 kHz of the inputted sound signal.

The level detector 3 detects the level of an output signal of the LPF 1 and when the detected level is equal to or higher than a predetermined value, a signal of H level (high level) is outputted, while when the detected level is lower than the predeterminedvalue, a signal of L level (low level) is outputted.

The level detector 4 detects the level of an output signal of the HPF 2, and when the detected level is equal to or higher than a predetermined value, a signal of H level (high level) is outputted, while when the detected level is lower than the predetermined value, a signal of L level (low level) is outputted.

The inverter 5 inverts the level of an output signal of the level detector 3. Namely, the inverter 5 outputs a signal of L level when the output signal of the level detector 3 is at the H level, and outputs a signal of H level when the output signal of the level detector 3 is at the L level.

The AND gate 6 operates an AND of an output signal of the inverter 5 and an output signal of the level detector 4. The integrator 7 integrates an output signal of the AND gate 6.

The VCA 8 attenuates the level of the output signal of the HPF 2 when an output signal of the integrator 7 is at the H level, and outputs the output signal of the HPF 2 without modification when the output signal of the integrator 7 is at the L level. The adder 9 synthesizes the output signal of the LPF 1 and an output signal of the VCA 8 by addition.

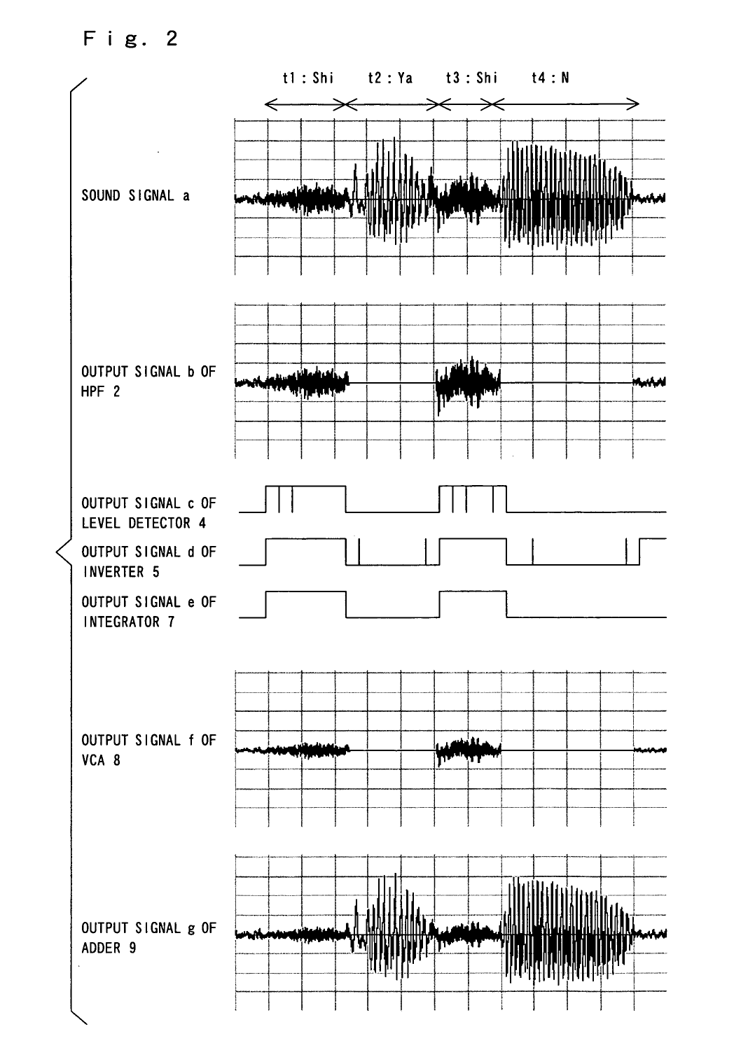

The operation of the sound quality adjusting device configured in this manner is described using FIGS. 2, 3 and 4. FIG. 2 is signal waveform diagrams of respective sections in the sound quality adjusting device of FIG. 1.

In FIG. 2, there are shown a sound signal a inputted into the LPF 1 and the HPF 2 of FIG. 1, an output signal b of the HPF 2, an output signal c of the level detector 4, an output signal d of the inverter 5, an output signal e of the integrator 7, an output signal f of the VCA 8, and an output signal g of the adder 9.

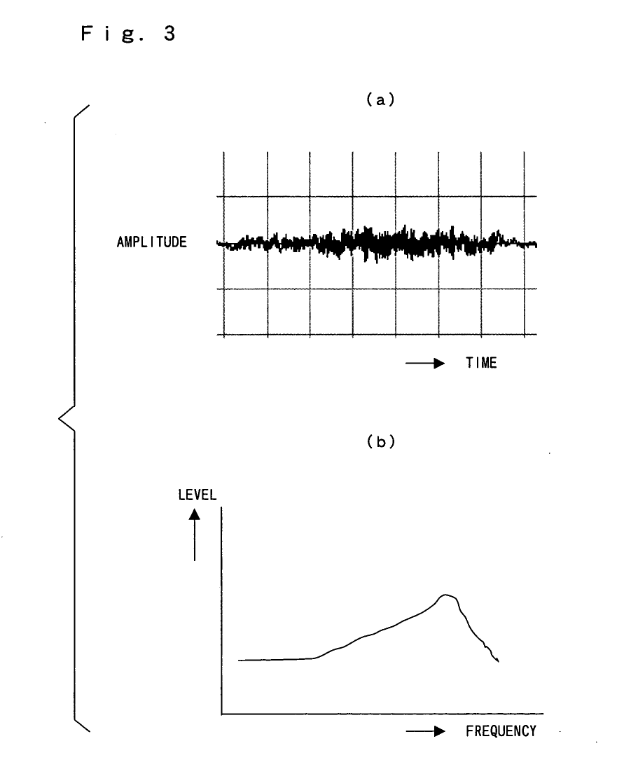

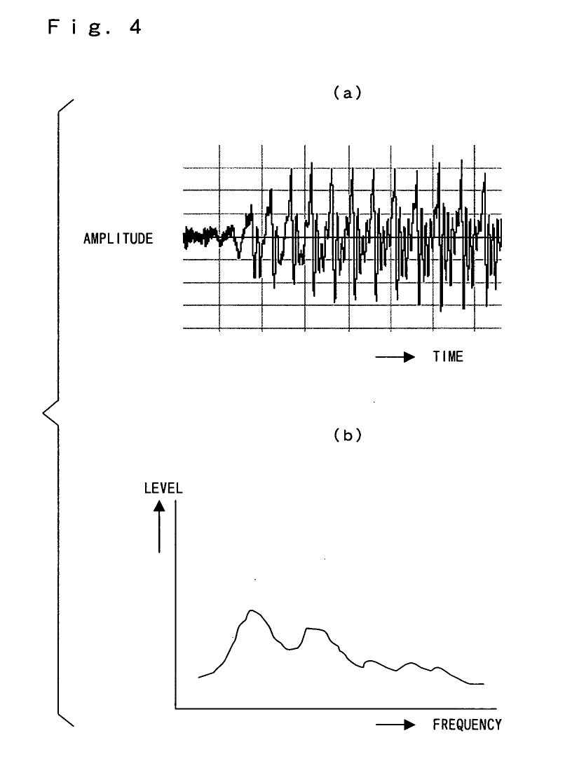

FIG. 3(a) is a diagram showing an example of a waveform of a sibilant and FIG. 3(b) is a diagram showing one example of a frequency spectrum of the sibilant. FIG. 4(a) is a diagram showing one example of a waveform of a normal speech sound, and FIG. 4(b) is adiagram showing one example of a frequency spectrum of the normal speech sound.

The abscissa of FIGS. 3(a) and 4(a) indicates time and the ordinate thereof indicates amplitude. The abscissa of FIGS. 3(b) and 4(b) indicates frequency and the ordinate thereof indicate level.

Normally, a sibilant has a spectrum component in a frequency band ranging from 5 kHz to 10 kHz. The sibilant of FIG. 3 shows a waveform and a frequency spectrum which have only a high frequency component of random noise. Meanwhile, a normal speech sound has a medium and low frequency component (formant component). Here, the formant component is a fundamental wave that a human voice has and its higher harmonic. The normal speech sound of FIG. 4 shows a waveform and a frequency spectrum in which the higher harmonic is superposed on the medium frequency fundamental wave.

In the sound quality adjusting device according to the present invention, by utilizing these characteristics of a sibilant and a normal speech sound, when the inputted sound signal a includes only a sibilant, the high frequency component is attenuated to reproduce the sound.

In the sound reproduction of a television receiver (television set), a sound base band signal obtained by detecting a sound signal of television broadcasting is inputted into the LPF 1 and the HPF 2 of FIG. 1 as the sound signal a.

The sound signal a shown in FIG. 2 is a speech time-series signal of “shashin”. Sibilants “shi” are uttered at sections t1, t3. At these sections t1, t3, the medium and low frequency component does not exist, and the high frequency component exists. At sections t2, t4, “ya” and “n” which are not sibilants are uttered. At the sections t2, t4, the medium and low frequency component and the high frequency component exist. The medium and low frequency component of the sound signal a passes through the LPF 1 and the high frequency component of the sound signal a passes through the HPF 2.

In the example of FIG. 2, in the output signal b of the HPF 2, the high frequency component by the sibilants exists at the sections t1, t3, and the medium and low frequency component at the sections t2, t4 is removed.

The level of the output signal b of the HPF 2 is detected by the level detector 4 in order to determine the presence of the high frequency component of the sound signal a. When the level of the output signal of the HPF 2 is equal to or higher than a predetermined value, the output signal c of the level detector 4 becomes the H level, and when the level of the output signal of the HPF 2 is lower than the predetermined value, the output signal c of the level detector 4 becomes the L level.

In the example of FIG. 2, the output signal c of the level detector 4 becomes the H level at the sections t1, t3 in which the high frequency component by the sibilants exists, and becomes the L level at the sections t2, t4 in which the high frequency component does not exist. In the present embodiment, the high frequency component other than the sibilant is also detected.

The level of the output signal of the LPF 1 is detected by the level detector 3 in order to determine the presence of the medium and low frequency component of the sound signal a. When the level of the output signal of the LPF 1 is equal to or higher than the predetermined value, the output signal of the level detector 3 becomes the H level, and when the level of the output signal of the LPF 1 is lower than the predetermined value, the output signal of the level detector 3 becomes the L level. The output signal of the level detector 3 is inverted by the inverter 5.

In the example of FIG. 2, the output signal d of the inverter 5 becomes the H level at the sections t1, t3 in which the medium and low frequency component does not exist, and become the L level at the sections t2, t4 in which the medium and low frequency component exists.

The output signal d of the inverter 5 is provided to one input terminal of the AND gate 6, and the output signal c of the level detector 4 is provided to the other input terminal of the AND gate 6. AND operation of the output signal d of the inverter 5 and the output signal c of the level detector 4 is performed by the AND gate 6.

In this case, only when the medium and low frequency component does not exist and the high frequency component exists, an output signal of the AND gate 6 becomes the H level. The output signal of the AND gate 6 has some chattering. Therefore, the output signal of the AND gate 6 is integrated by the integrator 7.

In the example of FIG. 2, the output signal e of the integrator 7 becomes the H level at the sections t1, t3 in which the medium and low frequency component does not exist and the high frequency component exists, and becomes the L level at the sections t2, t4 in which the medium and low frequency component exists.

A gain of the VCA 8 is controlled by the output signal e of the integrator 7. Thereby, the level of the high frequency component passing through the HPF 2 is controlled by the VCA 8. When the output signal e of the integrator 7 is at the H level, the level of the output signal b of the HPF 2 is attenuated by the VCA 8, and when the output signal e of the integrator 7 is at the L level, the output signal b of the HPF 2 is outputted without modification by the VCA 8.

In the example of FIG. 2, in the output signal f of the VCA 8, the level of the high frequency component by the sibilants at the sections t1, t3 is attenuated.

The medium and low frequency component passing through the LPF 1 and the high frequency component attenuated by the VCA 8 are added by the adder 9 to thereby be synthesized, so that the output signal g is obtained.

In the example of FIG. 2, in the output signal g of the adder 9, the sibilants at the sections t1, t3 are attenuated and the normal speech sounds at the t2, t4 are not attenuated.

As described above, in the sound quality adjusting device according to the present embodiment, it is determined that the sound signal at the sections t1, t3 in which the high frequency component exists and the medium and low frequency component does not exist is sibilants and the high frequency component is attenuated by the VCA8. This reduces the sibilants that sound harshly to the ear, so that the sound that is easy to hear is reproduced.

It is determined that the sound signal at the sections t2, t4 in which the medium and low frequency component exists is normal speech sounds and the attenuation of the high frequency component by the VCA 8 is not performed. This prevents deterioration in sound quality of the high frequency component. In this case, by outputting the medium and low frequency component and the high frequency component, a balanced sound which is easy to hear can be reduced.

Furthermore, since the presence of the medium and low frequency component and the high frequency component is detected using the level detectors 3, 4, a section having a sibilant can be determined precisely.

The extent of the attenuation of the high frequency component by the VCA 8 needs to be adjusted so as not to lower the high frequency component too much. For example, to attenuate the high frequency component by about 3 decibels to 10 decibels is preferable adjustment in terms of sound quality.

In the present embodiment, the LPF 1, the HPF 2, the level detector 3 and the level detector 4 constitute determination unit, and the VCA 8 and the adder 9 constitute controller. Furthermore, the LPF 1 corresponds to a first extractor or a low pass filter, the HPF 2 corresponds to a second extractor or a high pass filter, the level detector 3 corresponds to a first detector 3, the level detector 4 corresponds to a second detector, the AND gate 6 corresponds to a logical operation unit, the VCA 8 corresponds to an attenuator, and the adder 9 corresponds to a synthesizer.

Each of the sections of FIG. 1 may be made of hardware such as electronic circuit, or may be made of a computer including a CPU (central processing unit), a semiconductor memory and the like and software such as a program.

### Second Embodiment

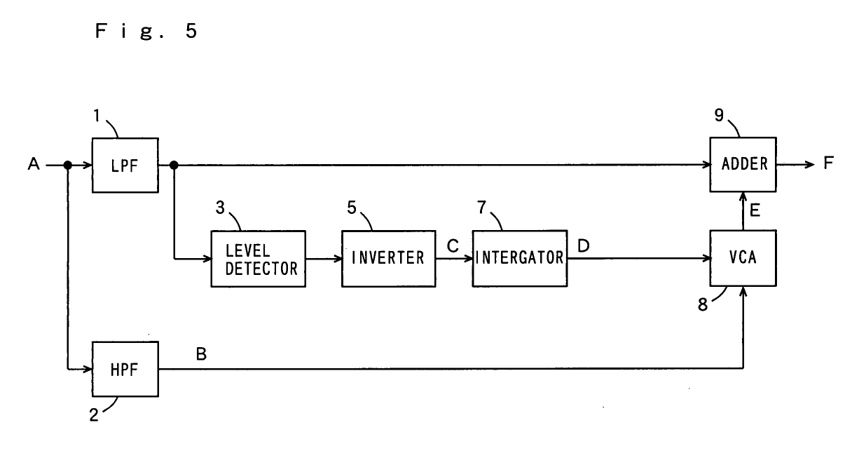

FIG. 5 is a block diagram showing a configuration of a sound quality adjusting device according to a second embodiment of the present invention.

The sound quality adjusting device of FIG. 5 includes the LPF 1, the HPF 2, the level detector 3, the inverter 5, the integrator 7, the VCA 8 and the adder 9.

The LPF 1 extracts a medium and low frequency component by passing a medium and low frequency component of not higher than 5 kHz of an inputted sound signal. The HPF 2 extracts a high frequency component by passing a high frequency component of not lower than 5 kHz of the inputted sound signal. The level detector 3 detects the level of an output signal of the LPF 1 and when the detected level is higher than a predetermined value, a signal of H level (high level) is outputted, while when the detected level is lower than the predetermined value, a signal of the L level (low level) is outputted.

The inverter 5 inverts the level of an output signal of the level detector 3. Namely, the inverter 5 outputs a signal of the L level when the output signal of the level detector 3 is at the H level, and outputs a signal of H level when the output signal of the level detector 3 is at the L level. The integrator 7 integrates the output signal of the inverter 5.

The VCA 8 attenuates the level of an output signal of the HPF 2 when an output signal of the integrator 7 is at the H level, and the output signal of the HPF 2 is outputted without modification when the output signal of the integrator 7 is at the L level. The adder 9 synthesizes the output signal of the LPF 1 and an output signal of the VCA 8 by addition.

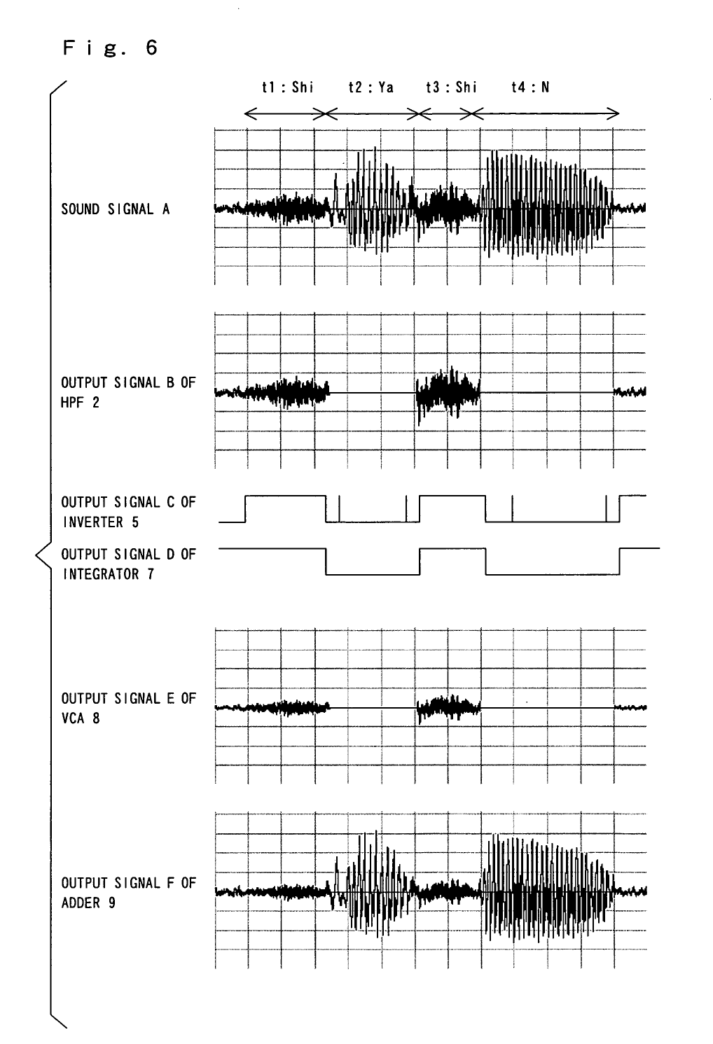

The operation of the sound quality adjusting device configured in this manner is described using FIG. 6. FIG. 6 is signal waveform diagrams of respective sections in the sound quality adjusting device of FIG. 5.

In FIG. 6, there are shown a sound signal A inputted into the LPF 1 and the HPF 2 of FIG. 5, an output signal B of the HPF 2, an output signal C of the inverter 5, an output signal D of the integrator 7, an output signal E of the VCA 8, and an output signal F of the adder 9.

As described above, normally, a sibilant has a spectrum component in a frequency band ranging from 5 kHz to 10 kHz. As shown in FIG. 3, the sibilant shows a waveform and a frequency spectrum which have only a high frequency component of random noise. Meanwhile, as shown in FIG. 4, a normal speech sound has a medium and low frequency component (formant component).

In the sound quality adjusting device according to the present invention, by utilizing these characteristics of a sibilant and a normal speech sound, when the inputted sound signal A includes only a sibilant, the high frequency component is attenuated to reproduce the sound.

In the sound reproduction of a television receiver (television set), a sound base band signal obtained by detecting a sound signal of television broadcasting is inputted into the LPF 1 and the HPF 2 of FIG. 5 as the sound signal A.

The sound signal A shown in FIG. 6 is a speech time-series signal of “shashin”. Sibilants “shi” are uttered at the sections t1, t3. At these sections t1, t3, the medium and low frequency component does not exist, and the high frequency component exists. At the sections t2, t4, “ya” and “n” which are not sibilants are uttered. At the sections t2, t4, the medium and low frequency component and the high frequency component exist. The medium and low frequency component of the sound signal A passes through the LPF 1 and the high frequency component of the sound signal A passes through the HPF 2.

In the example of FIG. 6, in the output signal B of the HPF 2, the high frequency component by the sibilants exists at the sections t1, t3, and the medium and low frequency component at the sections t2, t4 is removed.

The level of the output signal of the LPF 1 is detected by the level detector 3 in order to determine the presence of the medium and low frequency component of the sound signal A. When the level of the output signal of the LPF 1 is equal to or higher than the predetermined value, the output signal of the level detector 3 becomes the H level, and when the level of the output signal of the LPF 1 is lower than the predetermined value, the output signal of the level detector 3 becomes the L level. The output signal of the level detector 3 is inverted by the inverter 5.

In the example of FIG. 6, the output signal C of the inverter 5 becomes the H level at the sections t1, t3 in which the medium and low frequency component does not exist, and become at the L level at the sections t2, t4 in which the medium and low frequency component exists.

The output signal C of the inverter 5 has some chattering. Therefore, the output signal C of the inverter 5 is integrated by the integrator 7.

In the example of FIG. 6, the output signal D of the integrator 7 becomes the H level at the sections t1, t3 in which the medium and low frequency component does not exist, and becomes the L level at the sections t2, t4 in which the medium and low frequency component exists.

A gain of the VCA 8 is controlled by the output signal D of the integrator 7. Thereby, the level of the high frequency component passing through the HPF 2 is controlled by the VCA 8. When the output signal D of the integrator 7 is at the H level, the level of the output signal B of the HPF2 is attenuated by the VCA 8, and when the output signal D of the integrator 7 is at the L level, the output signal D of the HPF 2 is outputted without modification by the VCA 8.

In the example of FIG. 6, in the output signal E of the VCA 8, the level of the high frequency component by the sibilants at the sections t1, t3 is attenuated.

The medium and low frequency component passing through the LPF 1 and the high frequency component attenuated by the VCA 8 are added by the adder 9 to thereby be synthesized, so that the output signal F is obtained.

In the example of FIG. 6, in the output signal F of the adder 9, the sibilants at the sections t1, t3 are attenuated and the normal speech sounds at the t2, t4 are not attenuated.

As described above, in the sound quality adjusting device according to the present embodiment, it is determined that the sound signal at the sections t1, t3 in which the medium and low frequency component does not exist is sibilants and the high frequency component is attenuated by the VCA8. This reduces the sibilants that sound harshly to the ear, so that the sound that is easy to hear is reproduced.

Furthermore, it is determined that the sound signal at the sections t2, t4 in which the medium and the low frequency component exists is normal speech sounds, and the attenuation of the high frequency component by the VCA 8 is not performed. This prevents deterioration in sound quality of the high frequency component. In this case, by outputting the medium and low frequency component and the high frequency component, the balanced sound which is easy to hear can be reduced.

Moreover, since the presence of the sibilants are determined by detecting the presence of the medium and low frequency component using the level detector 3, the circuit configuration can be simplified.

The extent of the attenuation of the high frequency component by the VCA 8 needs to be adjusted so as not to lower the high frequency component too much. For example, to attenuate the high frequency component by about 3 decibels to 10 decibels is preferable adjustment in terms of sound quality.

In the present embodiment, the LPF 1 and the level detector 3 constitute determination unit, and the HPF 2, the VCA 8 and the adder 9 constitute controller. Furthermore, the LPF 1 corresponds to a first extractor or a low pass filter, the HPF 2 corresponds to a second extractor or a high pass filter, the level detector 3 corresponds to a detector, the VCA 8 corresponds to an attenuator, and the adder 9 corresponds to a synthesizer.

Each of the sections of FIG. 6 may be made of hardware such as electronic circuit, or may be made of a computer including a CPU, a semiconductor memory and the like and software such as a program.

### EXAMPLE

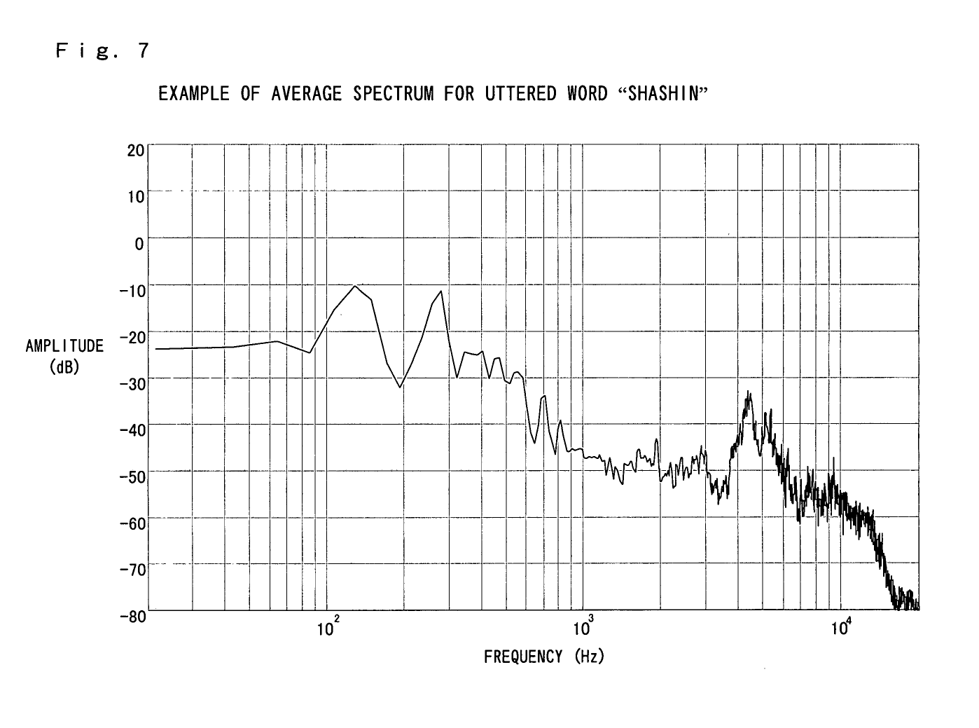

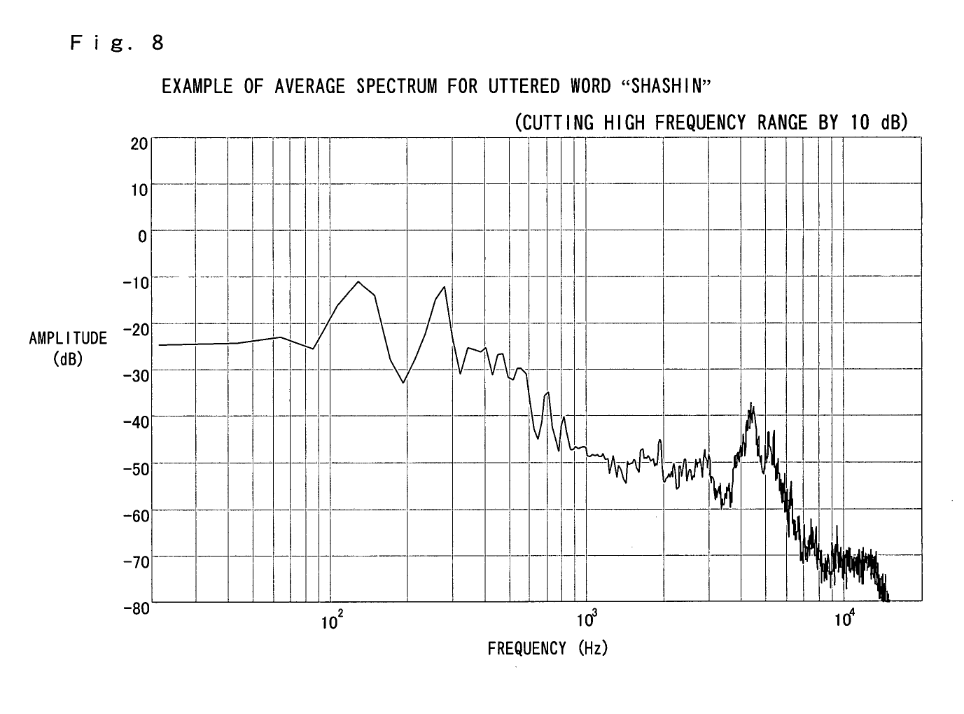

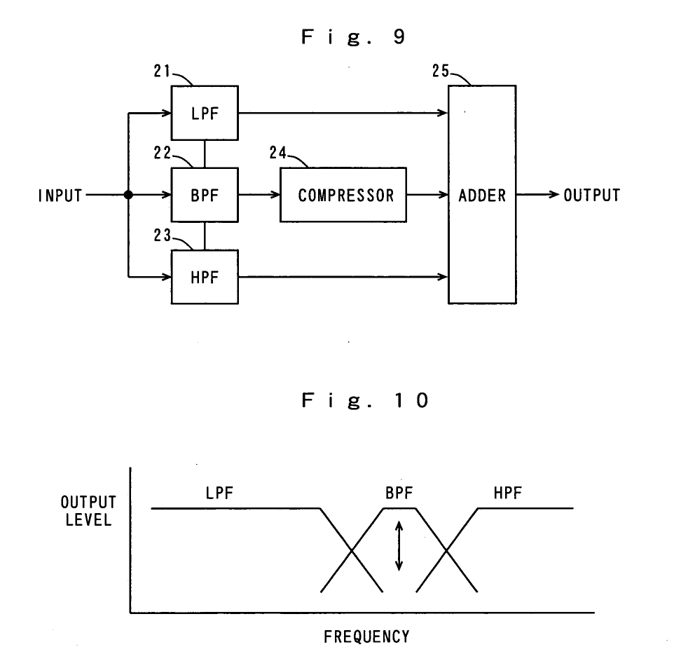

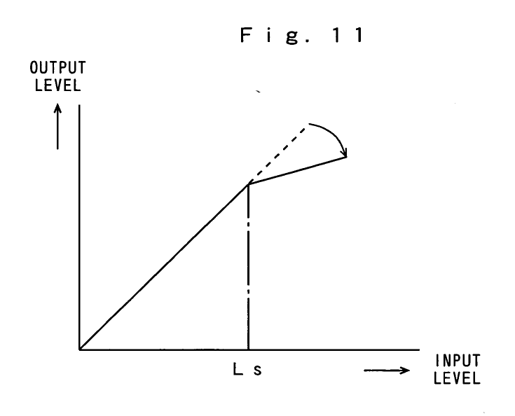

In the present example, the sound quality of the uttered word was adjusted using the sound quality adjusting device of FIG. 1. FIG. 7 is a diagram showing a measurement result of the spectrum of the uttered word. FIG. 8 is a diagram showing a measurement result of the spectrum of the voice sound whose sound quality has been adjusted. Here, the high frequency component of 5 kHz or higher was attenuated by 10 dB by the sound quality adjusting device of FIG. 1. The uttered word is “shashin”.

The abscissa of the FIGS. 7 and 8 indicates frequency and the ordinate thereof indicates amplitude. When comparing the spectrum of FIG. 8 with the spectrum of FIG. 7, the spectrum of FIG. 8 shows that the high frequency component of 5 kHz or higher in the spectrum of FIG. 7 has been attenuated. Thereby, the sibilants that sound harshly to the ear are attenuated, so that the sound easy to hear is reproduced.

### Other Modifications

While in the above-described first embodiment, the case where the AND gate 6 of positive logic is used is described, a sound quality adjusting device can also be easily realized using an NAND gate of negative logic.

Furthermore, while in the above-described embodiments, the VCA capable of continuously varying the gain as an attenuator is used, an attenuator capable of switching the gain in at least two steps may be used as the attenuator.

1. A sound quality adjusting device comprising:
a determination unit that determines whether a component of a predetermined first frequency band exists in an inputted sound signal; and
a controller that attenuates a component of a second frequency band higher than said first frequency band in said inputted sound signal and outputs the sound signal in which the component of said second frequency band is attenuated when said determination unit has determined that the component of said first frequency band does not exist, and that outputs said inputted sound signal without attenuating the component of said second frequency band in said inputted sound signal when said determination unit has determined that the component of said first frequency band exists.

2. The sound quality adjusting device according to claim 1, wherein
said determination unit determines that the component of said first frequency band exists when a level of the component of said first frequency band in said inputted sound signal is equal to or higher than a predetermined value, and determines that the component of said first frequency band does not exist when the level of the component of said first frequency band in said inputted sound signal is lower than said predetermined value.

3. The sound quality adjusting device according to claim 1, wherein
said determination unit includes:
a first extractor that extracts the component of said first frequency band in said inputted sound signal; and
a detector that detects whether a level of an output signal of said first extractor is equal to or higher than a predetermined value in order to determine whether the component of said first frequency band exists, and
said controller includes:
a second extractor that extracts the component of said second frequency band in said inputted sound signal;
an attenuator that attenuates a level of an output signal of said second extractor when said detector has detected that the level of the output signal of said first extractor is not equal to or higher than the predetermined value, and that outputs the output signal of said second extractor without attenuating when said detector has detected that the level of the output signal of said first extractor is equal to or higher than the predetermined value; and
a synthesizer that synthesizes the output signal of said first extractor and an output signal of said attenuator.

4. The sound quality adjusting device according to claim 3, wherein said determination unit further includes an integrator that integrates an output signal of said detector.

5. The sound quality adjusting device according to claim 3, wherein
said first extractor includes a low pass filter, and
said second extractor includes a high pass filter.

6. The sound quality adjusting device according to claim 1, wherein
said determination unit determines whether the component of said first frequency band and the component of said second frequency band exist in said inputted sound signal, and
said controller attenuates the component of said second frequency band in said inputted sound signal when said determination unit has determined that the component of said first frequency band does not exist and the component of said second frequency band exists.

7. The sound quality adjusting device according to claim 6, wherein
said determination unit determines that the component of said first frequency band exists when a level of the component of said first frequency band in said inputted sound signal is equal to or higher than the predetermined value, and that the component of said first frequency band does not exist when the level of the component of said first frequency band in said inputted sound signal is lower than said predetermined value, and
said determination unit further determines that the component of said second frequency band exists when a level of the component of said second frequency band in said inputted sound signal is equal to or higher than a predetermined value, and determines that the component of said second frequency band does not exist when the level of the component of said second frequency band in the inputted sound signal is lower than said predetermined value.

8. The sound quality adjusting device according to claim 6, wherein
said determination unit includes:
a first extractor that extracts the component of said first frequency band in said inputted sound signal;
a second extractor that extracts the component of said second frequency band in said inputted sound signal;
a first detector detects whether a level of an output signal of said first extractor is equal to or higher than a predetermined value in order to determine whether the component of said first frequency band exists; and
a second detector that detects whether a level of an output signal of said second extractor is equal to or higher than a predetermined value in order to determine whether the component of said second frequency band exists, and
said controller includes:
an attenuator that attenuates the level of the output signal of said second extractor when said first detector has detected that the level of the output signal of said first extractor is not equal to nor higher than the predetermined value and when said second detector has detected that the level of the output signal of said second extractor is equal to or higher than the predetermined value, and that outputs the output signal of said second extractor without attenuating when either said first detector has detected that the level of the output signal of said first extractor is equal to or higher than the predetermined value or said second detector has detected that the level of the output signal of said second extractor is not equal to nor higher than the predetermined value; and
a synthesizer that synthesizes the output signal of said first extractor and an output signal of said attenuator.

9. The sound quality adjusting device according to claim 8, wherein
said determination unit further includes:
an inverter that inverts an output signal of said first detector; and
a logical operation unit that calculates an AND of an output signal of said inverter and an output signal of said second detector, and
said attenuator either attenuates or does not attenuate, based on an output signal of said logical operation unit, the level of the output signal of said second extractor.

10. The sound quality adjusting device according to claim 9, wherein
said determination unit further includes an integrator that integrates the output signal of said logical operation unit.

11. The sound quality adjusting device according to claim 8, wherein
said first extractor includes a low pass filter, and
said second extractor includes a high pass filter.

12. The sound quality adjusting device according to claim 1, wherein
said first frequency band is within a frequency band not higher than 5 kHz, and
said first frequency band is within a frequency band not lower than 5 kHz.

13. A sound quality adjusting method comprising the steps of:
determining whether a component of a first frequency band equal to or lower than a predetermined frequency exists in an inputted sound signal; and
attenuating a component of a second frequency band higher than the predetermined frequency in said inputted sound signal and outputting the sound signal in which the second frequency band is attenuated when determined that the component of said first frequency band does not exist, and outputting said inputted sound signal without attenuating the component of said second frequency band in said inputted sound signal when determined that the component of said first frequency band exists.

14. The sound quality adjusting method according to claim 13, wherein
said step of determining includes the step of determining whether the component of said first frequency band and the component of said second frequency band exists in said inputted sound signal, and
said step of outputting includes the step of attenuating the component of said second frequency band in said inputted sound signal when determined that the component of said first frequency band does not exist and the component of said second frequency band exists.

15. The sound quality adjusting method according to claim 13, wherein
said first frequency band is within a frequency band not higher than 5 kHz; and
said first frequency band is within a frequency band not lower than 5 kHz.
